(19) United States
(12) Patent Application Publication
(10) Pub. No.: US 2008/0179616 A1
(43) Pub. Date: Jul. 31, 2008

(54) LED package

(76) Inventors: Seon Goo Lee, Gyunggi-do (KR); Geun Chang Ryo, Gyunggi-do (KR); Yong Tae Kim, Gyunggi-do (KR); Young Jae Song, Gyunggi-do (KR)

Correspondence Address: MCDERMOTT WILL & EMERY LLP, 600 13TH STREET, N.W., WASHINGTON, DC, 20005-3096, US

(21) Appl. No.: 12/007,371

(22) Filed: Jan. 9, 2008

(30) Foreign Application Priority Data
Jan. 9, 2007 (KR) 10-2007-0002599

(51) Int. Cl. H01L 33/00

(52) U.S. Cl. 257/98; 257/99; 257/E33.059; 257/E33.066

(57) ABSTRACT

There is provided an LED package. An LED package according to an aspect of the invention includes a package body including a concave part formed as a mounting section, first and second lead frames mounted to the package body to be exposed at a lower surface of the concave part, an LED chip mounted to the lower surface of the concave part to be electrically connected to the first and second lead frames, and an encapsulant formed by mixing transparent resin and a phosphor and formed inside the concave part to encapsulate the LED chip. Here, a height from an upper surface of the LED chip and an upper surface of the encapsulant is 1 to 5 times larger than that of the LED chip.

### CROSS-REFERENCE TO RELATED APPLICATIONS

This application claims the priority of Korean Patent Application No. 2007-02599 filed on Jan. 9, 2007, in the Korean Intellectual Property Office, the disclosure of which is incorporated herein by reference.

### BACKGROUND OF THE INVENTION

1. Field of the Invention

The present invention relates to an LED package, and more particularly, to an LED package that reduces a color deviation according to directions in which light is emitted and improvise light extraction efficiency.

2. Description of the Related Art

With the development of electronic equipment industry, various kinds of small and compact display devices with low power consumption have been developed. Further, optical devices using the display devices, such as video devices, computers, mobile communication terminals, and flashes, have been developed.

In general, a light emitting diode (LED) is a luminous element that generates light by luminescence (also called electroluminescence) caused when a voltage is applied to a semiconductor. The LED is formed of materials that have an emission wavelength in the visible or near-infrared region, have high luminous efficiency, and can be used to form p-n junctions. The materials may include compound semiconductors, such as gallium nitride (GaN), gallium arsenide (GaAs), gallium phosphide (GaP), gallium-arsenide-phosphide (GaAs₁₋ₓPₓ), gallium-aluminum-arsenide (Ga₁₋ₓAlₓAs), indium phosphide (InP), and indium-gallium-phosphide (In₁₋ₓGaₓP).

As compared with light sources according to the related art, the LED is small, has a long life-span, has a high energy efficiency, and has a low operating voltage because electric energy is directly converted to light energy. The LED having these advantages is being used as a light source of an LCD backlight module.

In order to use the LED as a white light source, a process of converting a wavelength of light emitted from the LED is required. Here, there are generally used techniques including a method of producing white light by exciting a yellow phosphor while using a blue LED as a light source and a method of exiting phosphors of three primary colors by using an ultraviolet LED as a light source.

FIG. 1 is a cross-sectional view illustrating a white LED package according to the related art.

Referring to FIG. 1, an LED package 10 according to the related art includes an LED chip 11, a package body 12, first and second lead frames 13a and 13b, a wire, and an encapsulant 14 formed to encapsulate the LED chip 11 in a concave part 16 of the package body 12. In general, a phosphor for wavelength conversion is included in the encapsulant 14 to emit white light.

In a process of fabricating the encapsulant 14, the encapsulant 14 is formed by injecting resin into the concave part 16. In the LED package 10 according to the related art, it is difficult to provide a uniform interface between the encapsulant 14 and the outside due to a difference in injection time.

When the interface between the encapsulant 14 and the outside is not uniform, paths along which light emitted from the LED chip 11 (indicated by an arrow) is emitted to the outside are greatly different from each other according to directions in which the light is emitted. Therefore, wavelength conversion is performed in a different manner by the phosphor according to the directions in which the light is emitted, which results in a high color deviation and a high deviation of light extraction efficiency according to directions in which the light is viewed from the outside.

Therefore, there is a need for a method of reducing the color deviation according to directions in which the light emitted from the LED package is viewed from the outside.

### SUMMARY OF THE INVENTION

An aspect of the present invention provides an LED package that reduces a color deviation according to directions in which light is emitted and improves light extraction efficiency.

According to an aspect of the present invention, there is provided an LED package including: a package body including a concave part formed as a mounting section; first and second lead frames mounted to the package body to be exposed at a lower surface of the concave part; an LED chip mounted to the lower surface of the concave part to be electrically connected to the first and second lead frames; and an encapsulant formed by mixing transparent resin and a phosphor and formed inside the concave part to encapsulate the LED chip. Here, a height from an upper surface of the LED chip and an upper surface of the encapsulant is 1 to 5 times larger than that of the LED chip.

The phosphor may be in the range of 30 to 300 wt % on the basis of the weight of the transparent resin.

A width of the lower surface of the concave part may be 1.5 to 3 times larger than that of the LED chip.

A height of the encapsulant may be the same as a depth of the concave part.

The concave part may have inner side walls inclined toward an upper part thereof on the basis of the lower surface.

The concave part may a circular or square traverse cross-section.

The phosphor may be composed of a plurality of kinds of materials emitting light at different wavelengths to absorb light emitted from the LED chip and emit white light.

The LED package may further include a lens formed on an upper part of the package body to cover the concave part.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view illustrating a white LED package according to the related art.

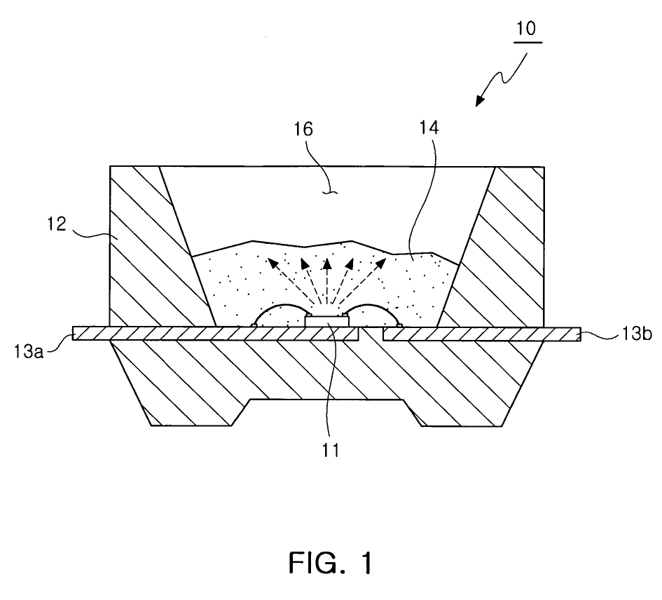

FIG. 2 is a cross-sectional view illustrating an LED package according to one exemplary embodiment of the present invention.

FIG. 3 is a cross-sectional view illustrating an LED package according to another exemplary embodiment of the present invention.

FIG. 4 is a graph illustrating a comparison of luminous flux efficiencies between an LED package according to the embodiment shown in FIG. 3 and an LED package according to the related art.

### DETAILED DESCRIPTION OF THE PREFERRED EMBODIMENT

Exemplary embodiments of the present invention will now be described in detail with reference to the accompanying drawings.

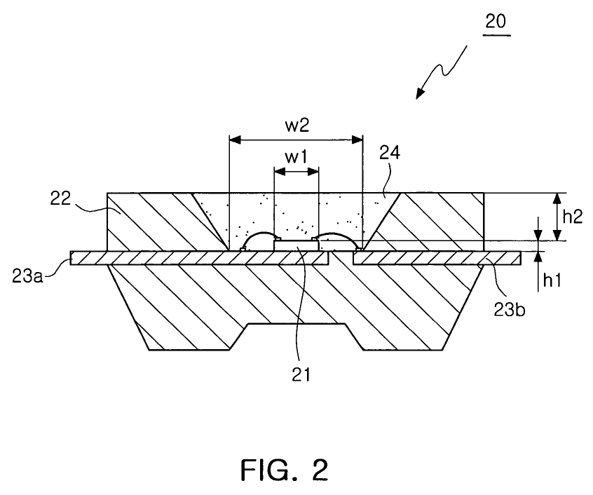

FIG. 2 is a cross-sectional view illustrating an LED package according to one exemplary embodiment of the present invention.

An LED package 20 according to one exemplary embodiment of the present invention includes an LED chip 21, a package body 22, first and second lead frames 23a and 23b, and an encapsulant 24 that is formed in a concave part of the package body 22.

The LED chip 21 includes first and second electrodes. The first and second electrodes are connected to first and second lead frames 23a and 23b, respectively, by a wire. The first and second lead frames 23a and 23b are extended outside the package body 22 along a longitudinal direction to thereby form external terminals.

In general, the package body 22 is formed by molding resin having high reflexibility. The first and second lead frames 23a and 23b are mounted to the package body 22. Further, the concave part for mounting the LED chip 21 and side walls around the concave part are formed at the package body 22. In this embodiment, in order to improve light extraction efficiency, the concave part has a structure in which inner side walls are inclined toward an upper part thereof on the basis of a lower surface of the concave part. The concave part having this structure guides the light emitted from the LED chip 21 toward the upper part.

The concave part is filled with transparent resin to form the encapsulant 24 for encapsulating the LED chip 21 from the outside is formed. The encapsulant 24 is obtained by mixing transparent resin and a phosphor capable of converting blue light or ultraviolet light generated from the LED chip 21 into white light. In this case, the phosphor may be composed of a plurality of kinds of materials that emit light at different wavelengths so as to absorb the light emitted from the LED chip 21 and emit white light.

In this embodiment, the phosphor that is contained in the encapsulant 24 is preferably in the range of 30 to 300 wt % on the basis of the weight of the transparent resin. As such, when the content of the phosphor contained in the encapsulant 24 is high, the viscosity increases. Therefore, the effect of a thin coating of the encapsulant 24 on the LED chip 21 can be achieved, which contributes to a reduction in the color deviation according to the directions in which the emitted light is viewed from the outside.

Further, as the viscosity increases, it is possible to reduce a ratio of the phosphor that sinks down the side of the LED chip 21. Unlike a flip-chip structure or the like, a thin GaN LED can improve color-conversion efficiency because light emitted toward the upper part accounts for approximately 97% of the total light amount. The increased viscosity allows the phosphor to be concentrated around the upper part of the LED chip, thereby improving color-conversion efficiency.

In this embodiment, as shown in FIG. 2, in terms of efficiency of the process, a height of the encapsulant 24 is preferably the same as a depth of the concave part. In this case, a length h2 from an upper surface of the LED chip 21 to an upper surface of the encapsulant 24 is 1 to 5 times larger than a height h1 of the LED chip 21. According to the structure of the concave part of the package body 22, the encapsulant 24 may be formed so that a thin coating of the encapsulant 24 is applied over the LED chip 21. As described above, when most of the light emitted from the LED chip 21 moves toward the upper part, the light extraction efficiency can be improved because the thickness of the coating of the encapsulant 24 is reduced.

In addition, a width W2 of a lower surface of the concave part is preferably 1.5 to 3 times larger than a width W1 of the LED chip. In this way, loss of light that is emitted toward the side of the LED chip 21 can be reduced as small as possible.

Though not shown in FIG. 2, the concave part may have a circular or square traverse cross-section.

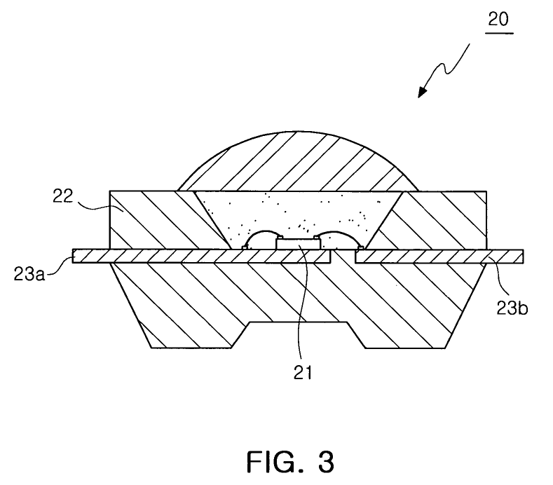

FIG. 3 is a cross-sectional view illustrating an LED package according to another exemplary embodiment of the present invention. Like the above-described embodiment shown in FIG. 2, an LED package 30 according to another exemplary embodiment of the invention includes an LED chip 31, a package body 32, first and second lead frames 33a and 33b, and an encapsulant 34 that encapsulates a concave part formed in the package body 32. The LED package 30 further includes a lens 35 that is formed on an upper part of the package body 32.

Other components are the same as those described in FIG. 2. The lens 35 on the upper part of the package body is formed to cover the concave part. The lens 35 refracts light generated from the LED chip 31 so that the light is emitted at a beam angle to improve the light extraction efficiency. Here, the lens 35 has a hemispherical shape and may be formed of transparent materials, such as plastic and glass.

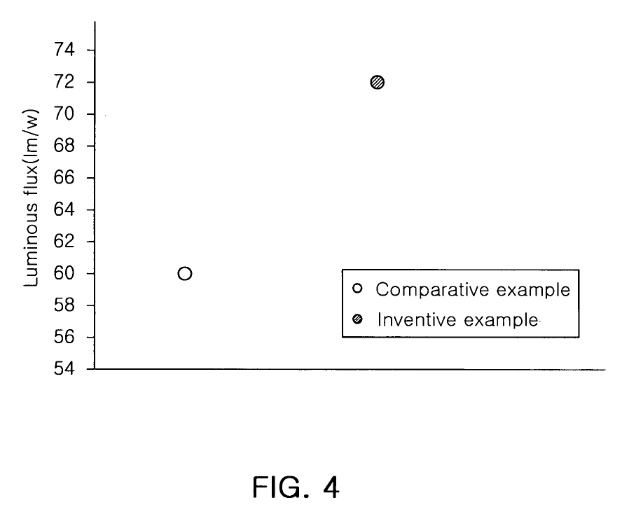

FIG. 4 is a graph illustrating a comparison of luminous flux efficiencies between the LED package according to the embodiment of FIG. 3 and the LED package according to the related art.

Referring to FIG. 4, the LED package according to the embodiment shown in FIG. 3, which is an inventive example, has a correlated color temperature (CCT) of 5900 to 6200K and luminous flux efficiency of 72 lm/W. Meanwhile, the LED package according to the embodiment shown in FIG. 3 (structure in which the lens is added to the upper part), which is a comparative example, has a correlated color temperature of 6000 to 6200K, and luminous flux efficiency of 60 lm/W. That is, in a case of the structure like the embodiment shown in FIG. 3, high luminous flux efficiency is obtained.

As set forth above, according to exemplary embodiments of the invention, an LED package that reduces a color deviation according to directions in which light is emitted and improves light extraction efficiency can be obtained.

While the present invention has been shown and described in connection with the exemplary embodiments, it will be apparent to those skilled in the art that modifications and variations can be made without departing from the spirit and scope of the invention as defined by the appended claims.

What is claimed is:

1. An LED package comprising:
a package body including a concave part formed as a mounting section;
first and second lead frames mounted to the package body to be exposed at a lower surface of the concave part;
an LED chip mounted to the lower surface of the concave part to be electrically connected to the first and second lead frames; and
an encapsulant formed by mixing transparent resin and a phosphor and formed inside the concave part to encapsulate the LED chip,
wherein a height from an upper surface of the LED chip and an upper surface of the encapsulant is 1 to 5 times larger than that of the LED chip.

2. The LED package of claim 1, wherein the phosphor is in the range of 30 to 300 wt % on the basis of the weight of the transparent resin.

3. The LED package of claim 1, wherein a width of the lower surface of the concave part is 1.5 to 3 times larger than that of the LED chip.

4. The LED package of claim 1, wherein a height of the encapsulant is the same as a depth of the concave part.

5. The LED package of claim 1, wherein the concave part has inner side walls inclined toward an upper part thereof on the basis of the lower surface.

6. The LED package of claim 1, wherein the concave part has a circular or square traverse cross-section.

7. The LED package of claim 1, wherein the phosphor is composed of a plurality of kinds of materials emitting light at different wavelengths to absorb light emitted from the LED chip and emit white light.

8. The LED package of claim 1, further comprising: a lens formed on an upper part of the package body to cover the concave part.
